(19) United States
(12) Patent Application Publication
(10) Pub. No.: US 2024/0178050 A1
(43) Pub. Date: May 30, 2024

(54) ADJACENT BURIED POWER RAIL FOR STACKED FIELD-EFFECT TRANSISTOR ARCHITECTURE

(71) Applicant: International Business Machines Corporation, Armonk, NY (US)

(72) Inventors: Nicholas Anthony Lanzillo, Wynantskill, NY (US); Albert M. Chu, Nashua, NY (US); Ruilong Xie, Niskayuna, NY (US); Biswanath Senapati, Mechanicville, NY (US); Seiji Munetoh, Inagi (JP); Lawrence A. Clevenger, Saratoga Springs, NY (US)

(21) Appl. No.: 18/059,098

(22) Filed: Nov. 28, 2022

(51) Int. Cl. H01L 21/74; H01L 21/822; H01L 23/528; H01L 23/535

(52) U.S. Cl. CPC H01L 21/743; H01L 21/8221; H01L 23/5286; H01L 23/535; H01L 27/0922

(57) ABSTRACT

One or more systems, devices, and/or methods of fabrication provided herein relate to adjacent buried power rail for stacked field-effect transistor architecture. According to one embodiment, a semiconductor device can comprise a first transistor stacked on a second transistor, wherein the first transistor is offset laterally from the second transistor, and a first buried power rail and a second buried power rail, wherein the first buried power rail is coupled to the first transistor and the second buried power rail is coupled to the second transistor.

### BACKGROUND

The subject disclosure relates to stacked field-effect transistors (FET), and more specifically to stacked FETs with buried power rail connections.

### SUMMARY

The following presents a summary to provide a basic understanding of one or more embodiments of the invention. This summary is not intended to identify key or critical elements, or delineate any scope of the particular embodiments or any scope of the claims. Its sole purpose is to present concepts in a simplified form as a prelude to the more detailed description that is presented later.

According to an embodiment, a semiconductor device can comprise a first transistor stacked on a second transistor, wherein the first transistor is offset laterally from the second transistor, and a power rail layer comprising a first buried power rail and a second buried power rail, wherein the first buried power rail is coupled to the first transistor and the second buried power rail is coupled to the second transistor. An advantage of such a device is that by laterally offsetting the first transistor and the second transistor, both the first transistor and the second transistor can be coupled to a power delivery system on the underside of the semiconductor device.

In some embodiments of the above-described device, the first buried power rail and the second buried power rail can be spaced unevenly within a cell. An advantage of such a device is that by spacing the power rails unevenly, decoupling capacitances can be increased, leading to better performance of the semiconductor device.

According to another embodiment, a method for fabricating a semiconductor device, by a fabrication system, can comprise, forming, by the fabrication system, a transistor region on a substrate, forming, by the fabrication system, an interconnect hierarchy on a top side of the transistor region, forming, by the fabrication system, a carrier wafer on top of the interconnect hierarchy, flipping, by the fabrication system, the semiconductor device onto the carrier wafer, removing, by the fabrication system, the substrate, and forming, by the fabrication system, two or more buried power rails within a cell.

In some embodiments of the above-described method, the transistor region can comprise a first transistor stacked on a second transistor, wherein the first transistor is offset laterally from the second transistor. An advantage of such a method is that by laterally offsetting the first transistor and the second transistor, both the first transistor and the second transistor can be coupled to a power delivery system on the underside of the semiconductor device.

According to another embodiment, a method for fabricating a semiconductor device, by a fabrication system, can comprise, stacking, by the fabrication system, a first transistor of the semiconductor device on a second transistor of the semiconductor device, wherein the first transistor is offset laterally from the second transistor, forming, by the fabrication system, a power rail layer comprising a first buried power rail and a second buried power rail; and coupling, by the fabrication system, the first buried power rail to the first transistor and the second buried power rail to the second transistor. An advantage of such a device is that by laterally offsetting the first transistor and the second transistor, both the first transistor and the second transistor can be coupled to a power delivery system on the underside of the semiconductor device.

### DESCRIPTION OF THE DRAWINGS

FIG. 1A illustrates a top-down view of an existing stacked FET architecture device.

FIG. 1B illustrates a cross-section view of an existing stacked FET architecture device.

FIG. 2A illustrates a top-down view of an example, non-limiting, stacked FET architecture device with buried power rails in accordance with one or more embodiments described herein.

FIGS. 2B and 2C illustrate cross-section of an example, non-limiting stacked FET architecture device with buried power rails in accordance with one or more embodiments described herein.

FIG. 3A illustrates a top-down view of an example, non-limiting, stacked FET architecture device with buried power rails in accordance with one or more embodiments described herein.

FIGS. 3B and 3C illustrate cross-sections of an example, non-limiting stacked FET architecture device with buried power rails in accordance with one or more embodiments described herein.

FIG. 4A illustrates a top-down view of a cell of an existing stacked FET architecture device.

FIG. 4B illustrates a top-down view of a cell of an example, non-limiting, stacked FET architecture device with buried power rails, in accordance with one or more embodiments described herein.

FIG. 4C illustrates a top-down view of a cell of an example, non-limiting, stacked FET architecture device with unevenly spaced buried power rails, in accordance with one or more embodiments described herein.

FIG. 5 illustrates a side view of an example, non-limiting, stacked FET architecture device with buried power rails, in accordance with one or more embodiments described herein.

FIG. 6 illustrates an example, non-limiting, flow diagram of a method of fabrication of a stacked FET semiconductor device with buried power rails in accordance with one or more embodiments described herein.

FIG. 7 illustrates stages of productions of an example, non-limiting, stacked FET device with buried power rails in accordance with one or more embodiments described herein.

FIG. 8 illustrates an example, non-limiting, flow diagram of a method of fabrication of a stacked FET semiconductor device with buried power rails in accordance with one or more embodiments described herein.

FIG. 9 illustrates a top-down view of a first stage of production of a semiconductor device, in accordance with one or more embodiments described herein.

FIGS. 10A, 10B and 10C illustrate cross-sections of a first stage of production of a semiconductor device, in accordance with one or more embodiments described herein.

FIGS. 11A, 11B and 11C illustrate cross-sections of a second stage of production of a semiconductor device, in accordance with one or more embodiments described herein.

FIGS. 12A, 12B and 12C illustrate cross-sections of a third stage of production of a semiconductor device, in accordance with one or more embodiments described herein.

FIGS. 13A, 13B and 13C illustrate cross-sections of a fourth stage of production of a semiconductor device, in accordance with one or more embodiments described herein.

FIGS. 14A, 14B and 14C illustrate cross-sections of a fifth stage of production of a semiconductor device, in accordance with one or more embodiments described herein.

FIGS. 15A, 15B and 15C illustrate cross-sections of a sixth stage of production of a semiconductor device, in accordance with one or more embodiments described herein.

FIGS. 16A, 16B and 16C illustrate cross-sections of a seventh stage of production of a semiconductor device, in accordance with one or more embodiments described herein.

FIGS. 17A, 17B and 17C illustrate cross-sections of an eighth stage of production of a semiconductor device, in accordance with one or more embodiments described herein.

FIGS. 18A, 18B and 18C illustrate cross-sections of a ninth stage of production of a semiconductor device, in accordance with one or more embodiments described herein.

FIGS. 19A, 19B and 19C illustrate cross-sections of a tenth stage of production of a semiconductor device, in accordance with one or more embodiments described herein.

FIGS. 20A, 20B and 20C illustrate cross-sections of an eleventh stage of production of a semiconductor device, in accordance with one or more embodiments described herein.

FIGS. 21A, 21B and 21C illustrate cross-sections of a twelfth stage of production of a semiconductor device, in accordance with one or more embodiments described herein.

### DETAILED DESCRIPTION

The following detailed description is merely illustrative and is not intended to limit embodiments and/or application or uses of embodiments. Furthermore, there is no intention to be bound by any expressed or implied information presented in the preceding Background or Summary sections, or in the Detailed Description section.

Buried power rails represent an opportunity for increases in decoupling capacitances in semiconductor devices, which in turn reduce power supply noise. These decoupling capacitances can be further increased by decreasing the space between the power rails. However, existing stacked FET architectures call for the buried power rails to be placed at cell boundaries, which in turn provides low decoupling capacitance due to the separation between the buried power rails. In existing stacked FET architectures, an n-channel field-effect transistor (NFET) is stacked on a p-channel field-effect transistor (PFET). As the PFET is stacked directly below the NFET, it is not possible to connect the NFET to a buried power rail, thus limiting the ability to group buried power rails together to increase decoupling capacitance.

In view of the aforementioned problems with current stacked FET devices, the described subject matter illustrates semiconductor devices and methods of fabrication of semiconductor devices capable of providing increased decoupling capacitances. For example, as described in greater detail below, a semiconductor device can comprise a first transistor stacked on a second transistor, wherein the first transistor is offset laterally from the second transistor, and a buried power rail layer comprising a first buried power rail and a second buried power rail, wherein the first buried power rail is coupled to the first transistor and the second buried power rail is coupled to the second transistor. As the first transistor and the second transistor are laterally offset from one and other, the second transistor does not block the first transistor from a buried power rail connection as is the case in existing stacked FET devices. Accordingly, both the first transistor and the second transistor can be coupled to buried power rails, which in turn can increase decoupling capacitances.

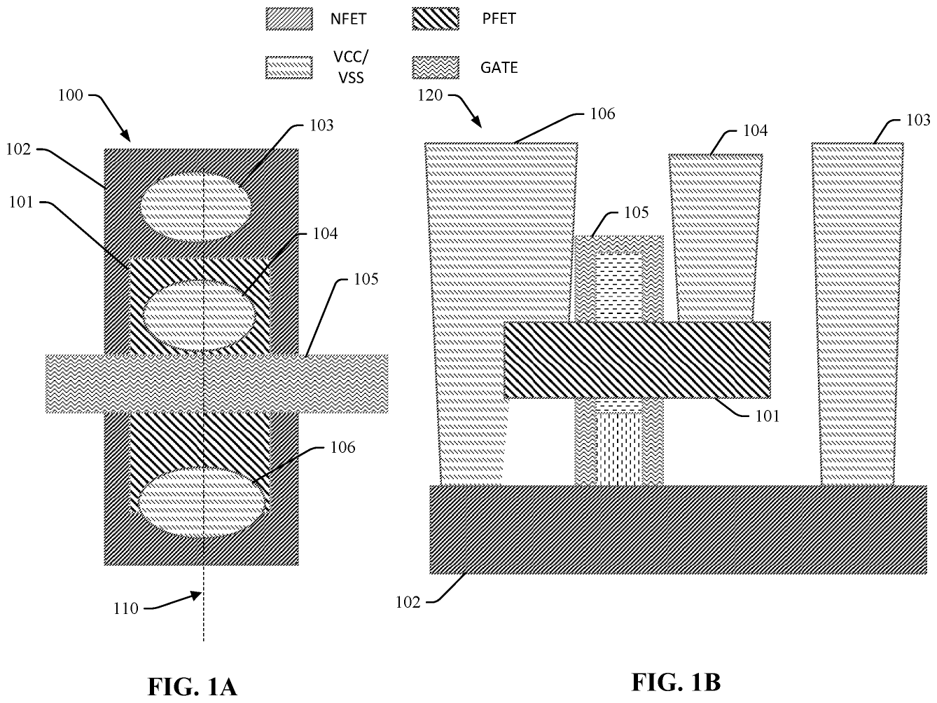

FIG. 1A illustrates a top-down view of an existing stacked FET architecture device 100. As shown, device 100 comprises an NFET 101, a PFET 101 stacked on top of the NFET 102, a VCC (voltage common collector) 103, a VSS (voltage source supply) 104, a gate 105 and a VOUT (voltage out) 106. FIG. 1B illustrates a cross-section view of device 100 along line 110. As shown by FIG. 1B, in existing stacked FET architectures, NFET 102 blocks PFET 101 from being able to connect to a buried power rail located below device 100.

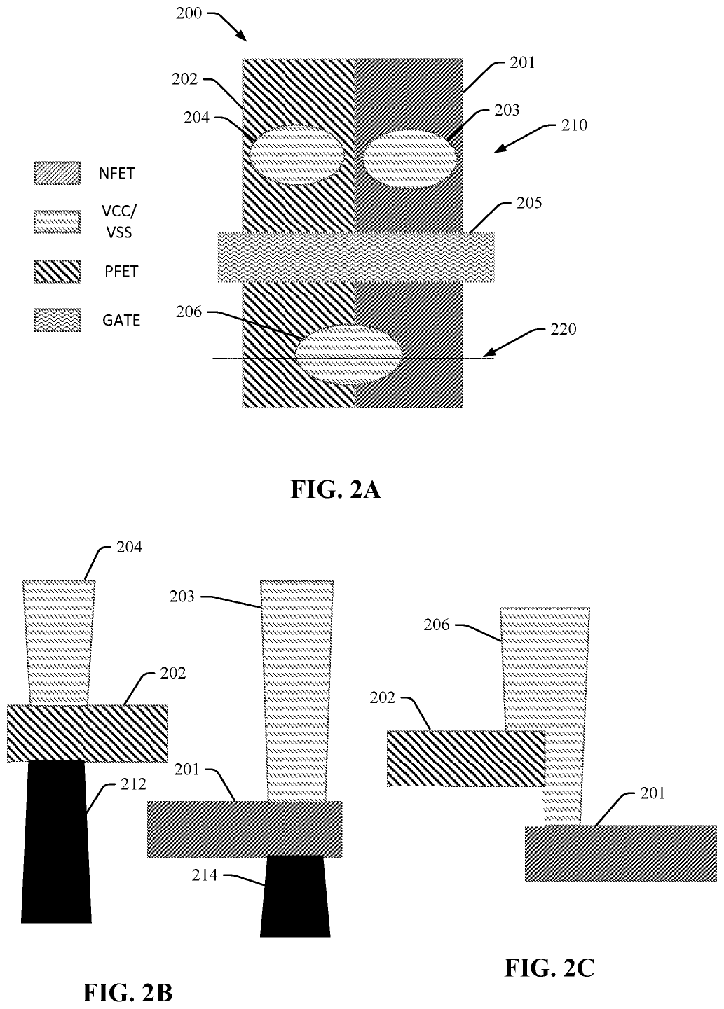

FIG. 2A illustrates a top-down view of an example, non-limiting, stacked FET architecture device 200 with buried power rails. As shown, device 200 can comprise an NFET 201, a PFET 202 stacked on top of the NFET 201, a VCC 203, a VSS 204, a gate 205 and a VOUT 206. FIG. 2B illustrates a cross-section of device 200 along line 210. As shown, PFET 202 is stacked on top of NFET 201, however, PFET 202 and NFET 201 are offset laterally from one and other such that NFET 201 does not block the bottom of PFET 202. Furthermore, as shown, PFET 202 is coupled to a first buried power rail 212 and NFET 201 is coupled to a second buried power rail 214. Additionally, as PFET 202 and NFET 201 can receive power from buried power rails 212 and 214 respectively. FIG. 2C illustrates a cross-section of device 200 along line 220. As shown, both PFET 202 and NFET 201 can be coupled to VOUT 206.

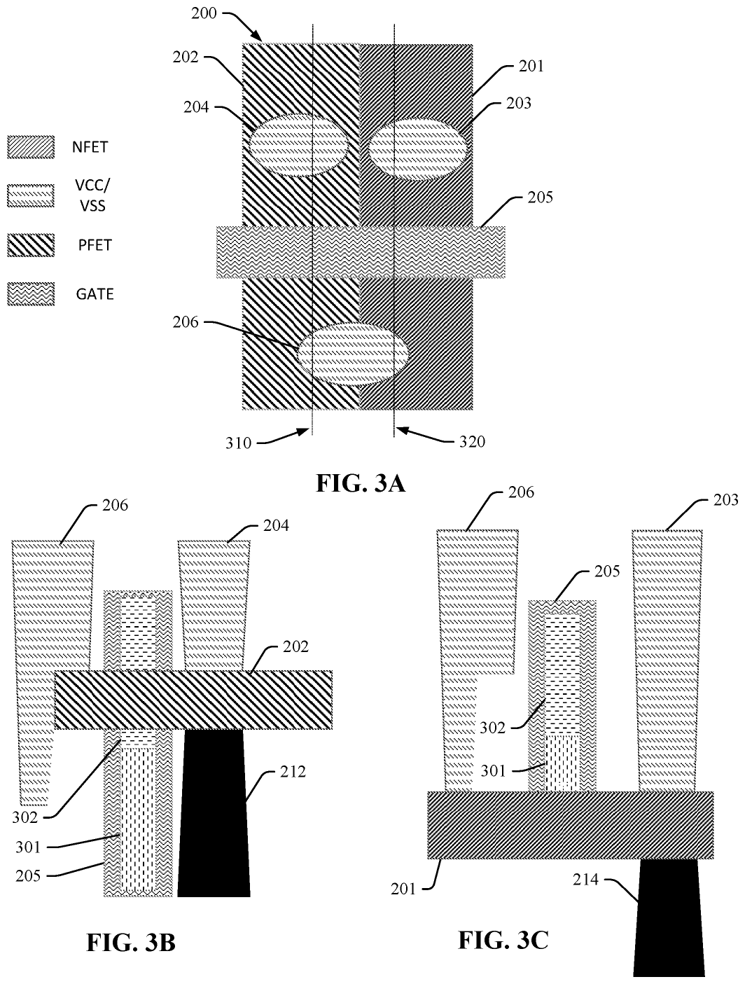

FIG. 3A illustrates a top-down view of stacked FET architecture device 200 with cross-section lines 310 and 320. FIG. 3B illustrates a cross-section of device 200 along line 310. As shown, PFET 202 is coupled to first buried power rail 212 and to gate 205. FIG. 3C illustrates a cross-section of device 200 along line 320. As shown, NFET 201 is coupled to second buried power rail 214 and to gate 205. As illustrated by FIGS. 3A, 3B and 3C, in one or more embodiments, gate 205 can be orientated perpendicular to PFET 202 and NFET 201. Furthermore, in one or more embodiments, gate 205 can comprise an p-work form metals region 302 coupled to PFET 202 and a n-work form metals region 301 coupled to NFET 201.

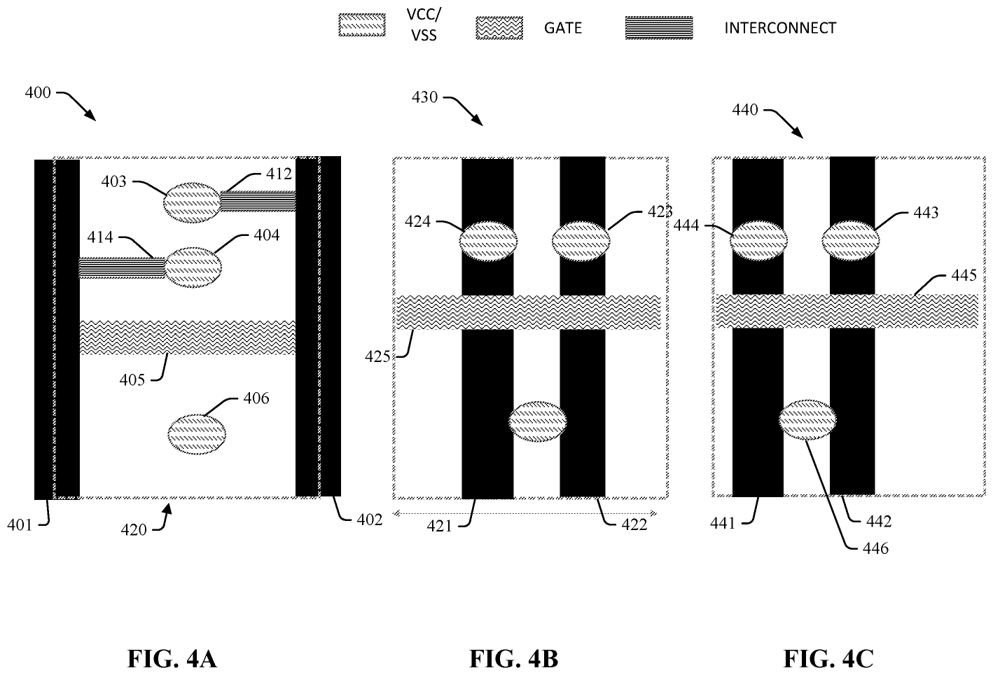

FIG. 4A illustrates a top-down view of a cell of an existing stacked FET architecture device 400. As shown, device 400 comprises a VCC 403, a VSS 404, a gate 405, a VOUT 406, a first power source 401 and a second power source 402. As described above in reference to FIG. 1, in existing stacked FET devices, the NFET blocks access to the bottom of the PFET. Accordingly, as shown by device 400 power sources 401 and 402 are located at the edges of cell boundary 420 and local interconnects 412 and 414 supply power from first power source 401 and second power source 402 to VCC 403 and VSS 404 respectively. This distance between power sources 401 and 402 limits the decoupling capacitance of device 400.

FIG. 4B illustrates a top-down view of a cell of a non-limiting stacked FET architecture device 430 with buried power rails. As shown, device 430 comprises a VCC 423, a VSS 424, a gate 425, a VOUT 426, a first buried power rail 421 and a second buried power rail 422. As described above in reference to FIG. 2, by laterally offsetting the PFET and the NFET, the NFET does not block access to the bottom of the PFET, allowing for the first buried power rail 421 to supply power to the PFET. Accordingly, the first buried power rail and the second buried power rail can be placed closer to one and other within cell boundary 420, thereby increasing decoupling capacitance. FIG. 4C illustrates a top-down view of a cell of a non-limiting stacked FET architecture device 440 with unevenly spaced buried power rails. As shown, first buried power rail 441 and second buried power rail 442 are spaced unevenly within cell boundary 420 (e.g., not centered within cell boundary 420).

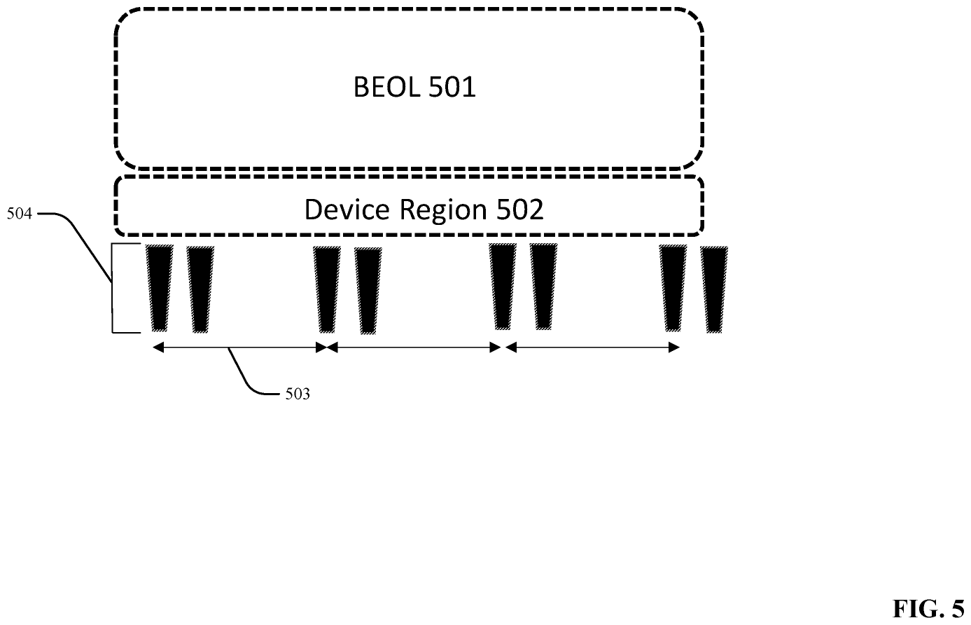

FIG. 5 illustrates a side view of an example, non-limiting stacked FET architecture device 500 with buried power rails. As shown, device 500 can comprise back end of line (BEOL) region 501 (e.g., an interconnect hierarchy) coupled to a device region 502. In an embodiment, the BEOL region 501 can enable coupling of the device region 502 to one or more additional devices. In an embodiment, device region 502 can comprise one or more cells, wherein the one or more cells comprise a first transistor stacked on a second transistor, wherein the first transistor and the second transistor are laterally offset. The one or more cells can further comprise two or more buried power rails 504, wherein the first buried power rail of the two or more buried power rails 504 can be coupled to the first transistor and a second buried power rail of the two or more buried power rails 504 can be coupled to the second transistor. As shown by FIG. 5, the first buried power rail and the second buried power rail can be spaced unevenly within a cell (e.g., not located centrally within width 503) and can be located close to one and other (e.g., a distance less than the height of a cell) to increase decoupling capacitance.

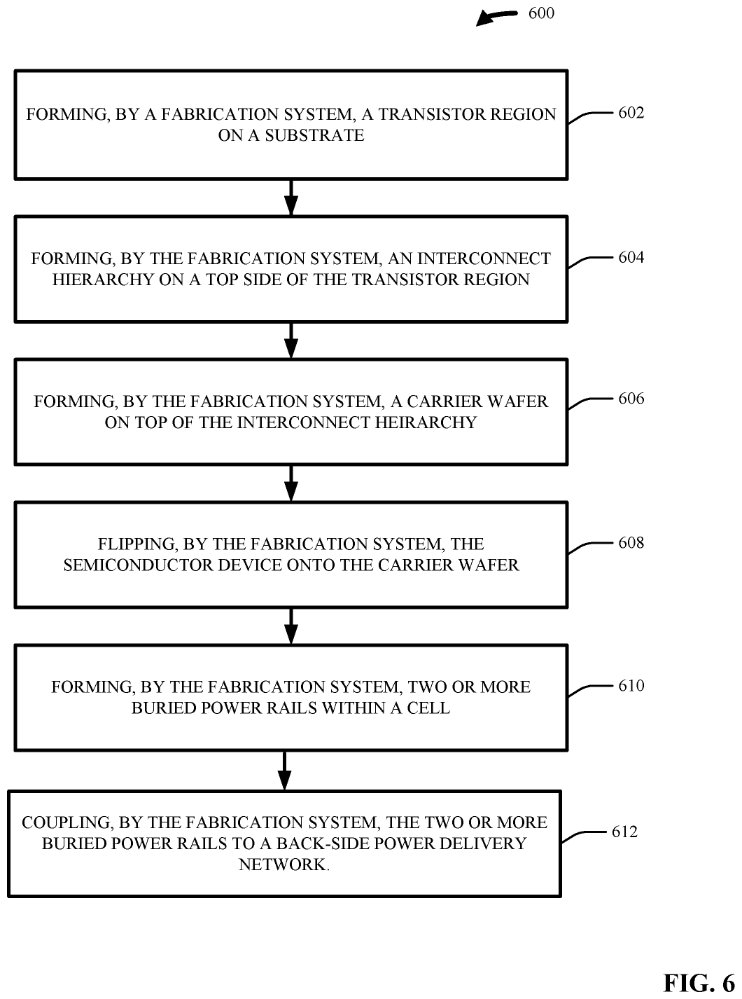

FIG. 6 illustrates an example, non-limiting, flow diagram of a method of fabrication 600 of a stacked FET device with buried power rails in accordance with one or more embodiments described herein.

At 602, method 600 can comprise forming, by a fabrication system, a transistor region on a substrate. In an embodiment, the transistor region can comprise a first transistor stacked on top of a second transistor, wherein the first transistor is laterally offset from the second transistor. In further embodiment, the first transistor and the second transistor can comprise at least one of a PFET or an NFET. For example, the first transistor can comprise a PFET, and the second transistor can comprise an NFET. In another example, the first transistor can comprise an NFET, and the second transistor can comprise a PFET. In an embodiment, the transistor region can be formed by a nanosheet production method.

At 604, method 600 can comprise forming, by the fabrication system, an interconnect hierarchy on a top side of the transistor region. In an embodiment, a back end of line process can be utilized to form the interconnect hierarchy. Furthermore, in an embodiment, the interconnect hierarchy can enable operative coupling between the transistor region and one or more additional devices.

At 606, method 600 can comprise forming, by the fabrication system, a carrier wafer on top of the interconnect hierarchy. For example, a wafer can be formed on the top of the interconnect hierarchy by a water wafer bonding or deposition process.

At 608, method 600 can comprise flipping, by the fabrication system, the semiconductor device onto the carrier wafer. Furthermore, a portion of the substrate can be removed via an etching process to form a thin substrate.

At 610, method 600 can comprise, forming, by the fabrication system, two or more buried power rails within a cell. In an embodiment, channels can be etched into the substrate for the two or more buried rails, and a metallization process can be utilized to form two or more buried power rails within the channels. In an embodiment, the channels can be positioned to allow a first buried power rail of the two or more buried power rails to be coupled to the first transistor and a second buried power rail of the two or more buried power rails to be coupled to the second transistor. In a further embodiment, a buried power rail can be coupled to a via, wherein the via is coupled to a transistor.

At 612, method 600 can comprise, coupling, by the fabrication system, the two or more buried power rails to a backs-side power delivery network. For example, by coupling the two or more buried power rails to the back-side delivery network, the two or more buried power rails can provide power to the transistor region from the underside of the semiconductor device.

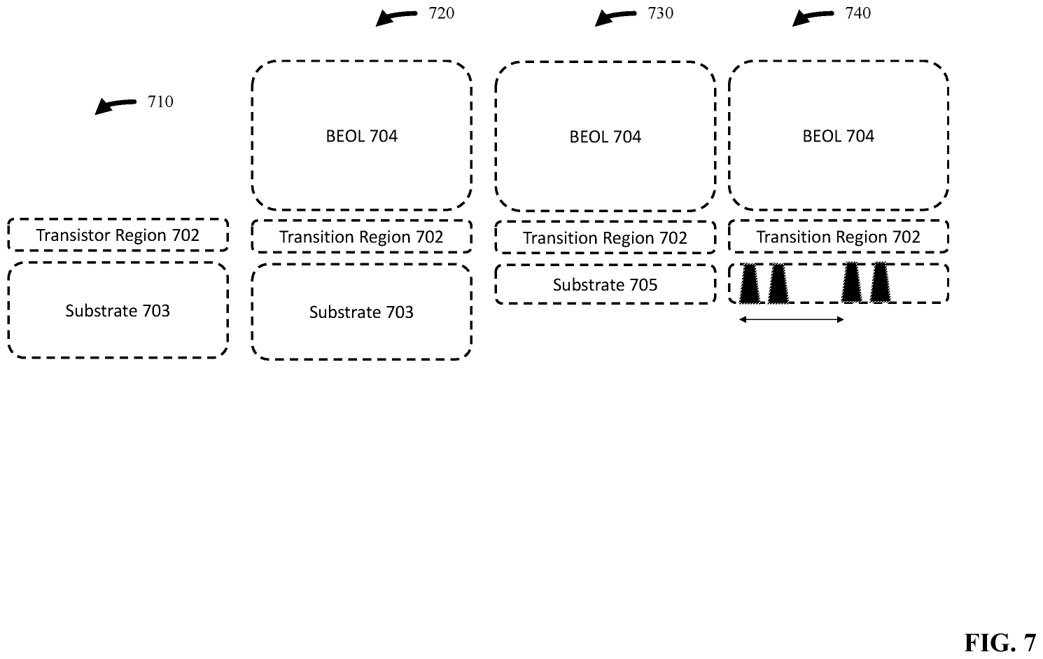

FIG. 7 illustrates stages of productions of an example, non-limiting stacked FET device with buried power rails. At stage 710, a transistor region 702 can be formed on a substrate 703. In an embodiment, transistor region 702 can comprise a first transistor stacked on a second transistor, wherein the first transistor and the second transistor are laterally offset. For example, transistor region 702 can comprise one or more cells comprising the stacked FET architecture illustrated in greater detail above in reference to FIGS. 2A, 2B, 2C, 3A, 3B and 3C. At stage 720, a BEOL region 704 can be formed on top of the transistor region 702. In an embodiment, BEOL region 704 can enable operative coupling between the transistor region 702 and one or more additional devices. At stage 730, the substrate 703 can be thinned to produce substrate 705. For example, the device can be flipped over and substrate 703 can be thinned to produce substrate 705. At stage 740, two or more buried power rails can be formed. For example, one or more channels can be etched through substrate 705. A metallization process can then be utilized to produce the two or more buried power rails. In an embodiment, the two or more buried power rails can be adjacent to one and other as described above in greater detail in reference to FIGS. 2A-4B.

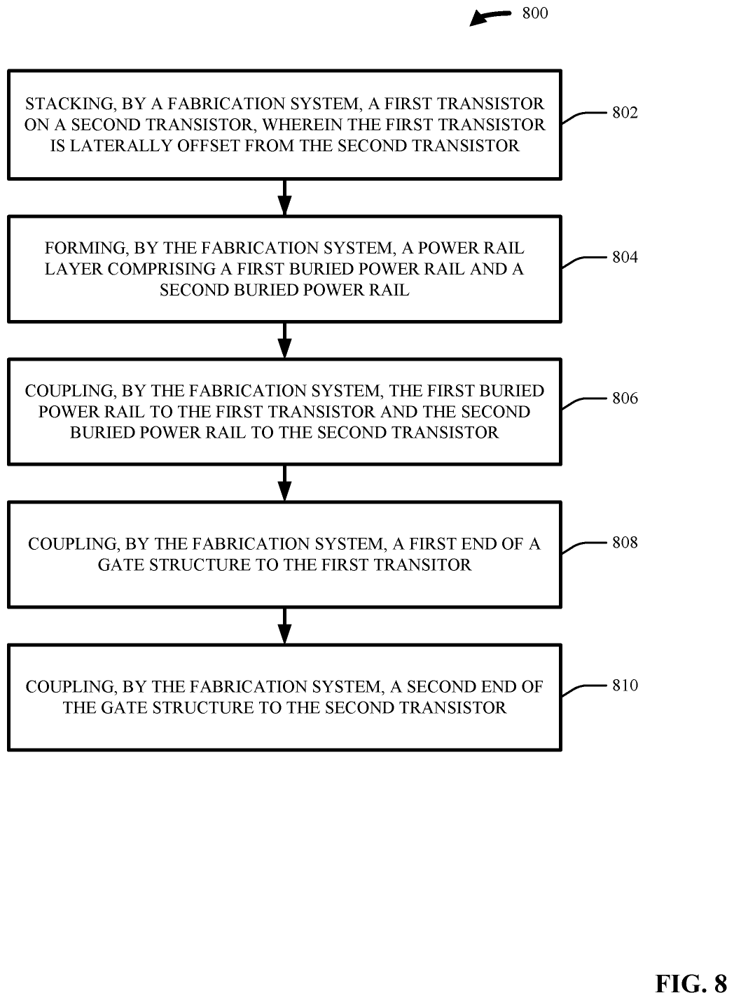

FIG. 8 illustrates an example, non-limiting, flow diagram of a method of fabrication 800 of a stacked FET semiconductor device with buried power rails in accordance with one or more embodiments described herein.

At 802, method 800 can comprise stacking, by a fabrication system, a first transistor on a second transistor, wherein the first transistor is laterally offset from the second transistor. For example, the first transistor and the second transistor can be laterally offset as shown in greater detail above in reference to FIGS. 2A-3C. In a further embodiment, the first transistor and the second transistor can comprise at least one of an NFET or a PFET. For example, the first transistor can comprise a PFET, and the second transistor can comprise an NFET. In a further example, the first transistor can comprise an NFET, and the second transistor can comprise a PFET.

At 804, method 800 can comprise forming, by the fabrication system, a power rail layer comprising a first buried power rail and a second buried power rail. In an embodiment, the first buried power rail and the second buried power rail can be formed by etching two or more channels into a substrate and filing the two or more channels with a metallization process. In a further embodiment, the first buried power rail and the second buried power rail can be spaced uneven within a cell as described in greater detail above in reference to FIG. 4C.

At 806, method 800 can comprise coupling, by the fabrication system, the first buried power rail to the first transistor and the second buried power rail to the second transistor. In an embodiment, the channels used to form the first buried power rail and the second buried power rail can be placed such that the first buried power rail couples directly to the first transistor and the second buried power rail couples directly to the second transistor. In a further embodiment, a buried power rail may be coupled to a via, wherein the via is coupled to a transistor.

At 808, method 800 can comprise coupling, by the fabrication system, a first end of a gate structure to the first transistor. For example, if the first transistor comprises a PFET, then the first end of the gate structure can comprise a P-WFM (positive work function metal). In another example, if the first transistor comprises a NFET, the first end of the gate structure can comprise a N-WFM (negative work function metal).

At 810, method 800 can comprise coupling, by the fabrication system, a second end of the gate structure to the second transistor. For example, if the second transistor comprises a PFET, then the second end of the gate structure can comprise a P-WFM. In another example, if the second transistor comprises a NFET, the second end of the gate structure can comprise a N-WFM.

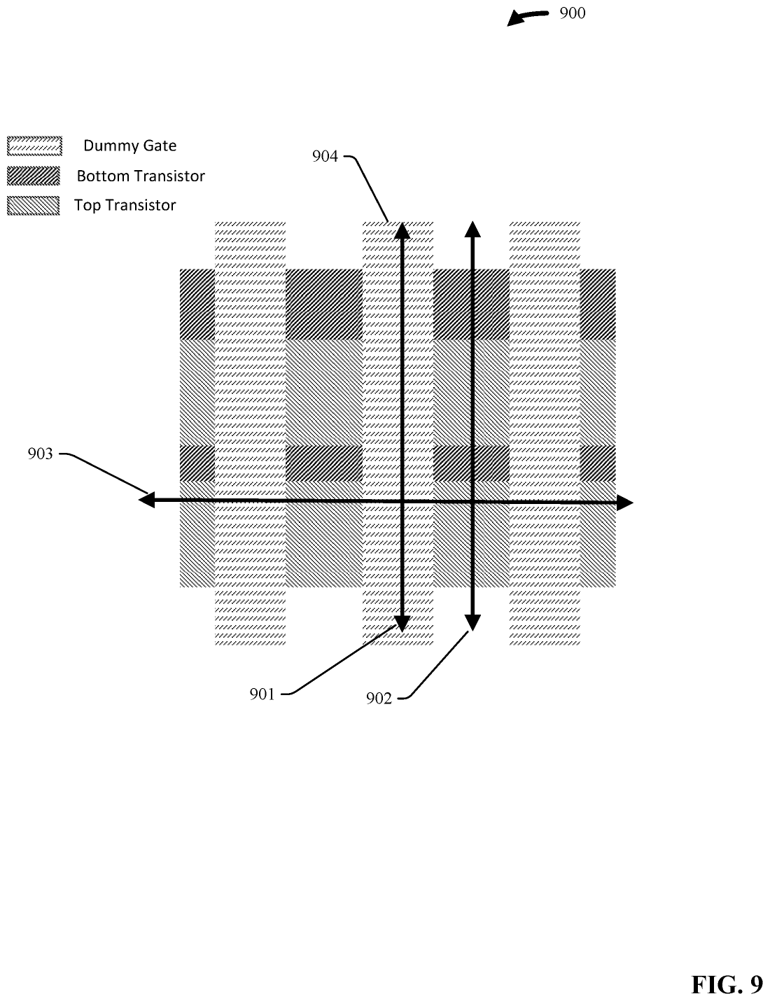

FIG. 9 illustrates a top-down view of a first stage of production of a semiconductor device 900, in accordance with one or more embodiments described herein. As shown, device 900 can comprise one or more substrate sections 904. As described in greater detail below, substrate section 904 can comprise a first transistor and a dummy gate. Lines 901, 902 and 903 illustrate various directions of cross-sections utilized to describe further production of device 900 as described in greater detail below.

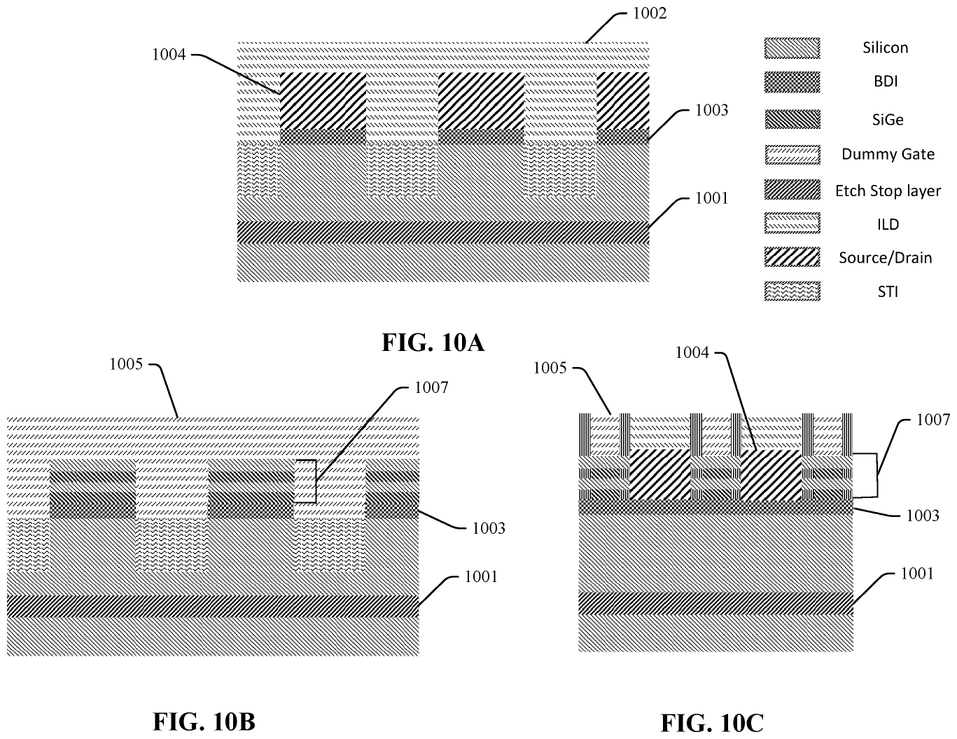

FIGS. 10A, 10B and 10C illustrate cross-sections of a first stage of production of semiconductor device 900 in accordance with one or more embodiments described herein. FIG. 10A illustrates a cross-section along line 901 of device 900. As shown, FIG. 10A comprises an etch-stop layer 1001 (e.g., bonding oxide or SiO₂), an inner layer dielectric 1002, a bottom dielectric insulator (BDI), and one or more source/drain epis 1004. FIG. 10B illustrates a cross-section along line 902 of device 900. As shown, FIG. 10B comprises a first transistor device 1007 and a dummy gate 1005. In an embodiment, the first transistor device 1007 can comprise PFETs or NFETs. In an embodiment, the first transistor device 1007 can comprise alternating layers of Si and SiGe. FIG. 10C illustrates a cross-section along line 903 of device 900. As shown, FIG. 10C comprises an alternate view of dummy gate 1005, the first transistor device 1007, and source/drain epis 1004.

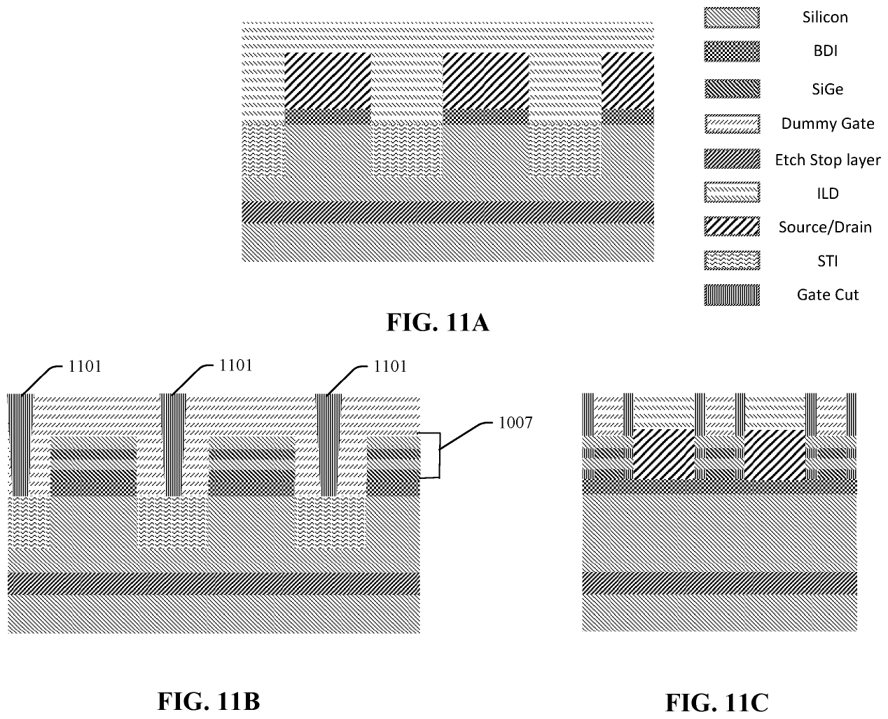

FIGS. 11A, 11B and 11C illustrate cross-sections of a second stage of production of device 900 in accordance with one or more embodiments described herein. FIG. 11B illustrates a cross-section along line 902 of device 900. FIG. 11B comprises one or more bottom gate cuts 1101 to enable production of gates for the first transistor device 1007.

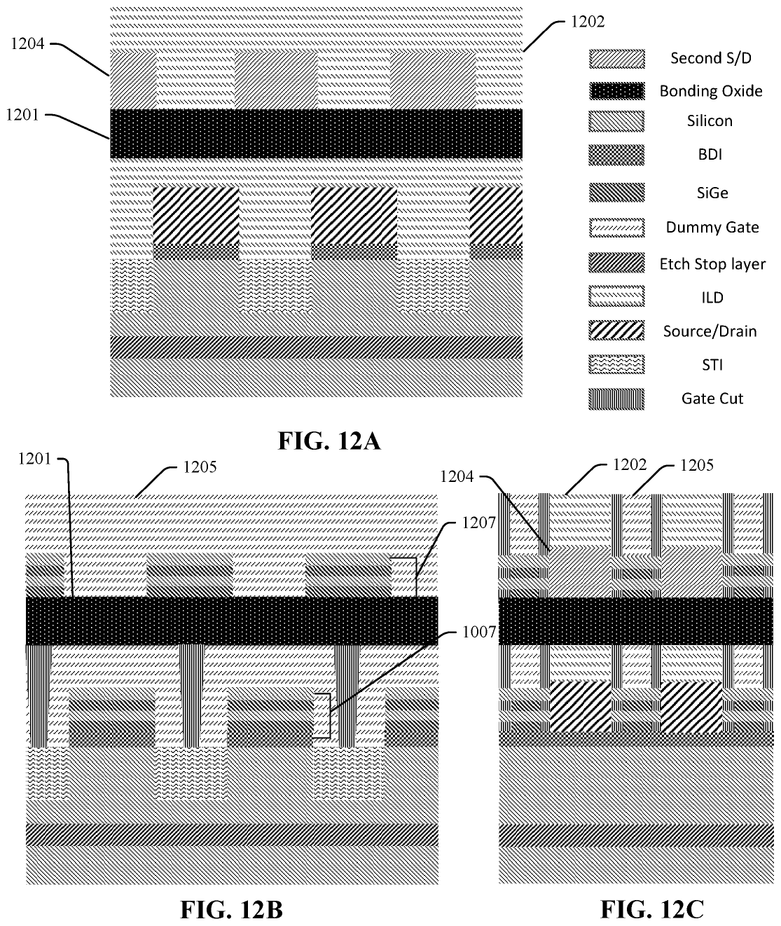

FIGS. 12A, 12B and 12C illustrate cross-sections of a third stage of production of device 900 in accordance with one or more embodiments described herein. At this stage of production, a second wafer comprising a second transistor device 1207 can be wafer bonded on to dummy gate 1005. FIG. 12A illustrates a cross-section along line 901 of device 900. FIG. 12A comprises bonding oxide 1201 that can bond the second wafer to the first, a second inner layer dielectric 1202, and a second set of source/drain epis 1204. FIG. 12B illustrates a cross-section along line 902 of device 900. FIG. 12B comprises a second dummy gate 1205 and a second transistor device 1207. In an embodiment, the second transistor device 1207 can comprise PFETs or NFETs. In an embodiment, the second transistor device 1207 can comprise alternating layers of Si and SiGe. In some embodiment, the first transistor device 1007 and the second transistor device 1207 can comprise the same number of Si layers, in other embodiments, the first transistor device and the second transistor device can comprise different numbers of Si layers. It should be appreciated that as shown the first transistor device 1007 is laterally offset from the second transistor device 1207. FIG. 12C illustrates a cross-section alone line 903 of device 900.

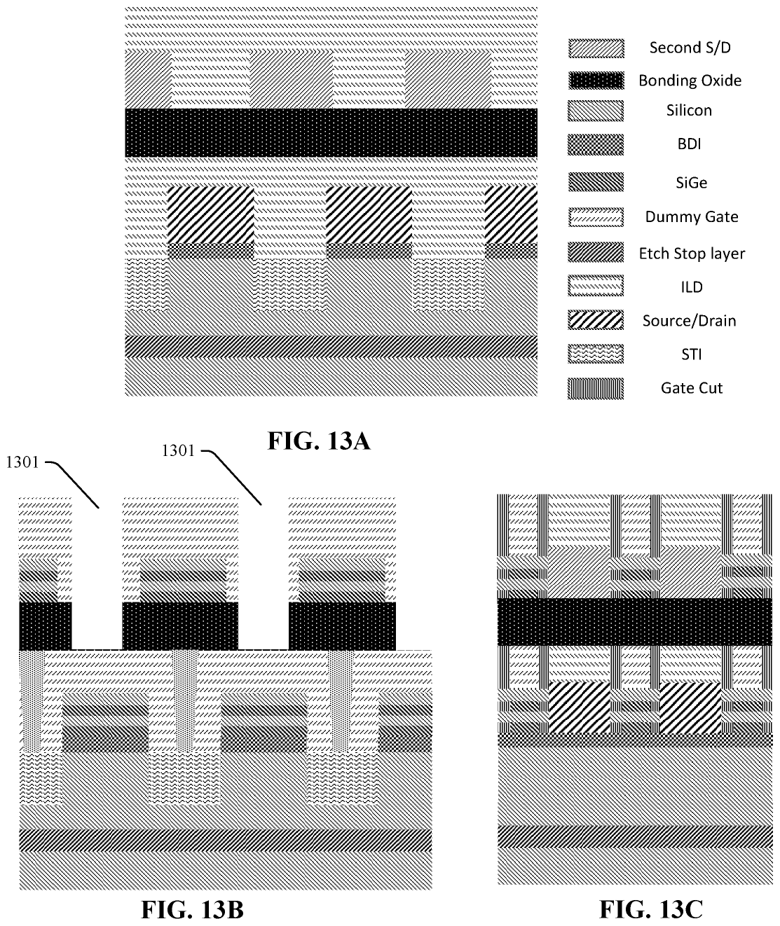

FIGS. 13A, 13B and 13C illustrate cross-sections of a fourth stage of production of device 900 in accordance with one or more embodiments described herein. FIG. 13B illustrates a cross-section along line 902 of device 900. FIG. 13B comprises one or more gate patterning cuts 1301 to enable formation of gates.

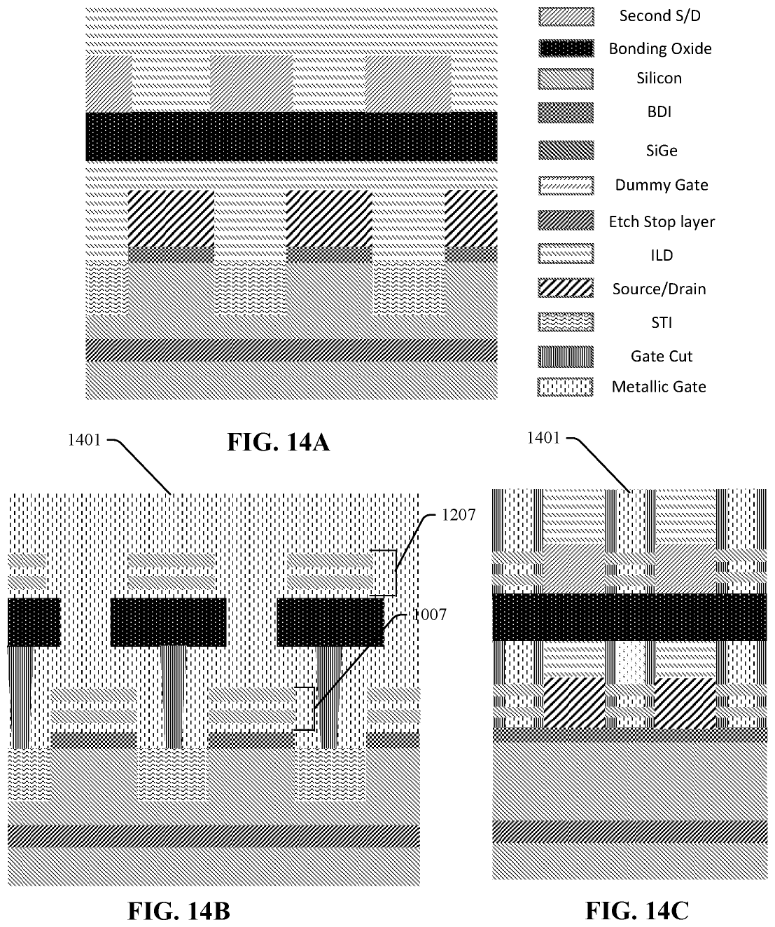

FIGS. 14A, 14B and 14C illustrate cross-sections of a fifth stage of production of device 900 in accordance with one or more embodiments described herein. FIG. 14B illustrates a cross-section along line 902 of device 900. As shown by FIGS. 14B and 14C dummy gate 1005, second dummy gate 1205 and layers of SiGe from the first transistor device 1007 and the second transistor device 1207 can be removed and a high-k metallic gate 1401 can be formed.

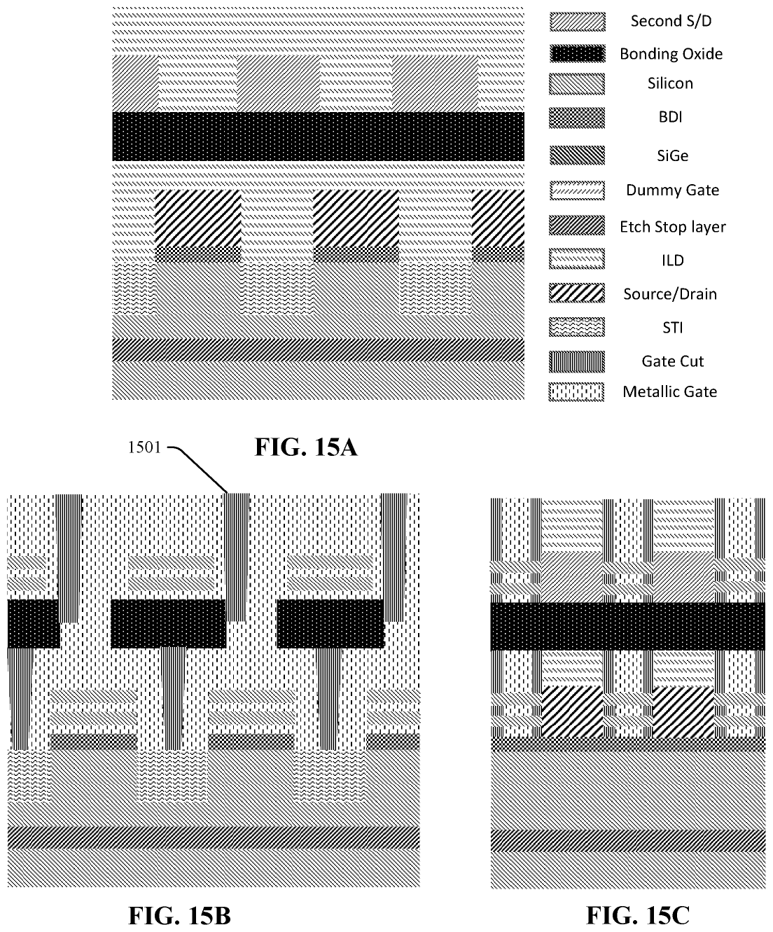

FIGS. 15A, 15B and 15C illustrate cross-sections of a sixth stage of production of device 900 in accordance with one or more embodiments described herein. FIG. 15B illustrates a cross-section along line 902 of device 900. FIG. 15B comprises one or more top gate cuts 1501 to enable production of gates for the second transistor device 1207.

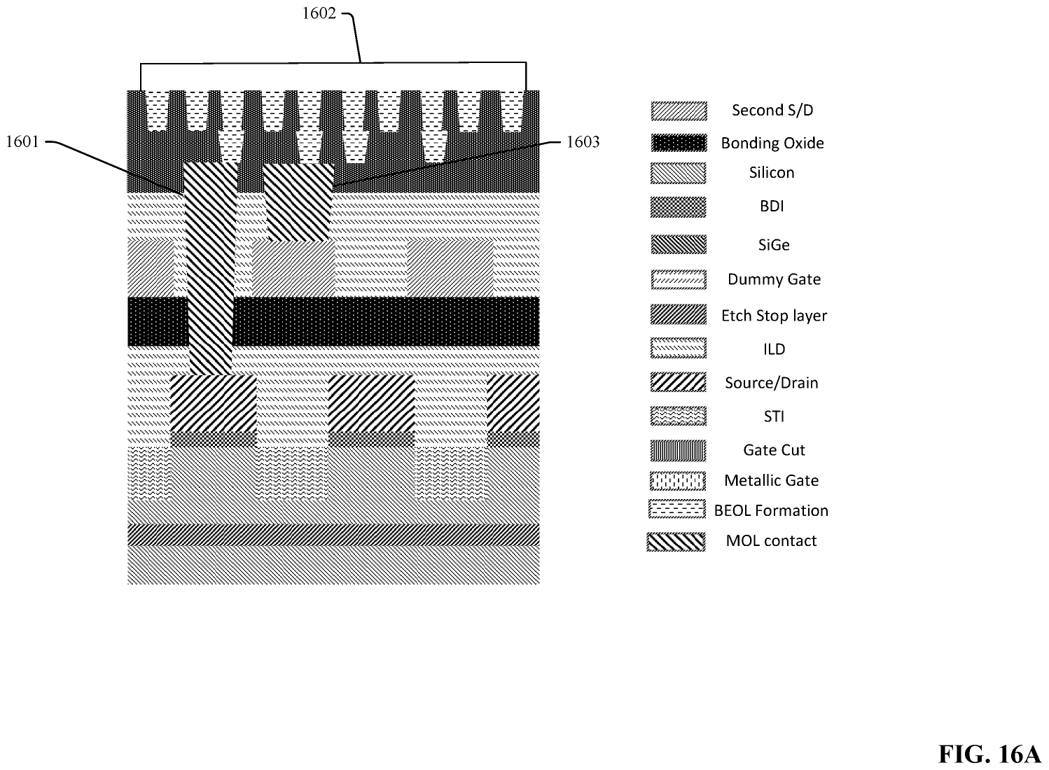

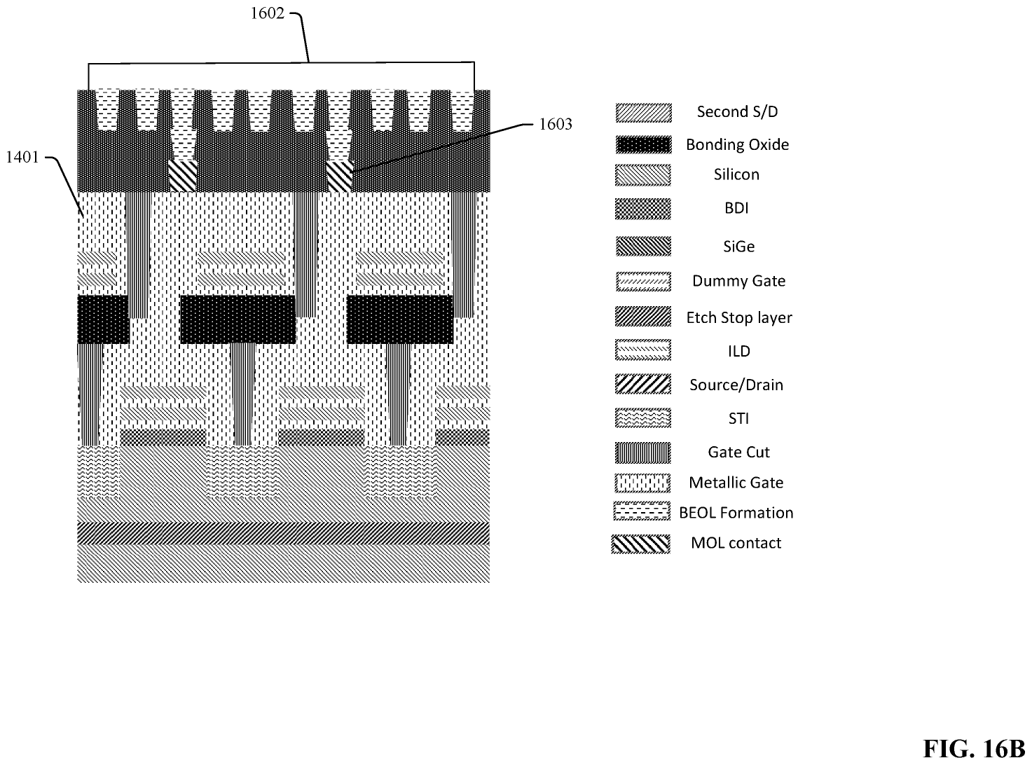

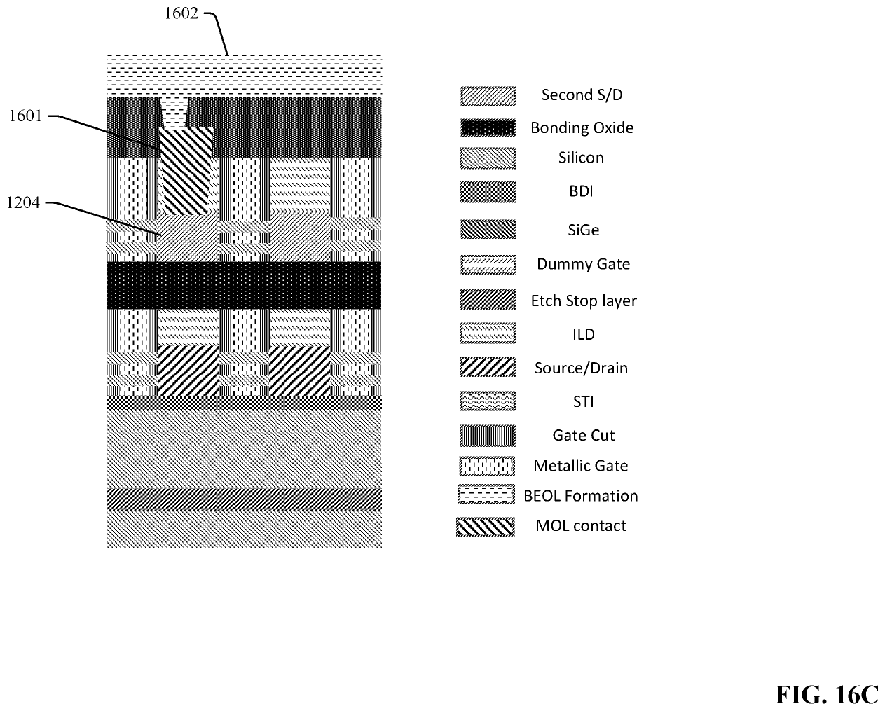

FIGS. 16A, 16B and 16C illustrate cross-sections of a seventh stage of production of device 900 in accordance with one or more embodiments described herein. FIG. 16A illustrates a cross-section along line 901 of device 900. FIG. 16A comprises a first middle of line (MOL) connector 1601 which connects to source/drain epi 1004 and a second MOL connector 1603 which connects to gate 1401. FIG. 16A further comprises a lower BEOL formation 1602. Lower BEOL formation 1602 can comprise one or more vias and one or more connector lines. FIG. 16B illustrates a cross-section along line 902 of device 900. As FIG. 16B illustrates, second MOL connector 1603 can connect the lower BEOL formation 1602 to the metallic gate 1401. FIG. 16C illustrates a cross-section along line 903 of device 900. As FIG. 16C illustrates, first MOL connector 1601 can connect source/drain epi 1204 to lower BEOL formation 1602.

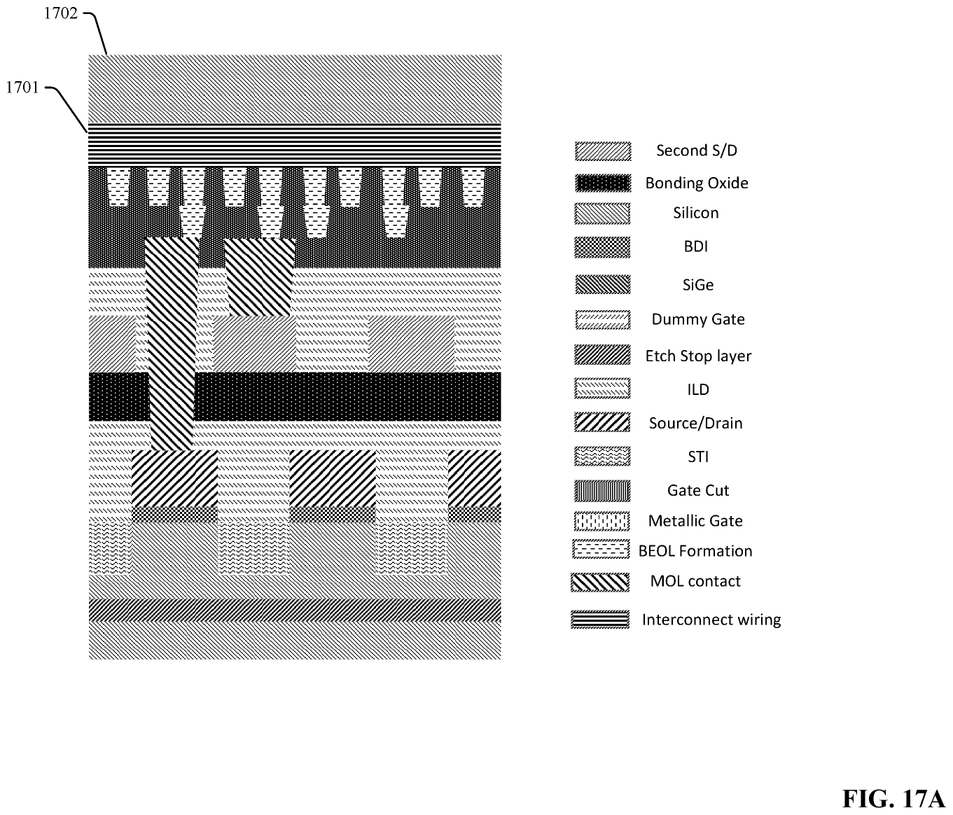

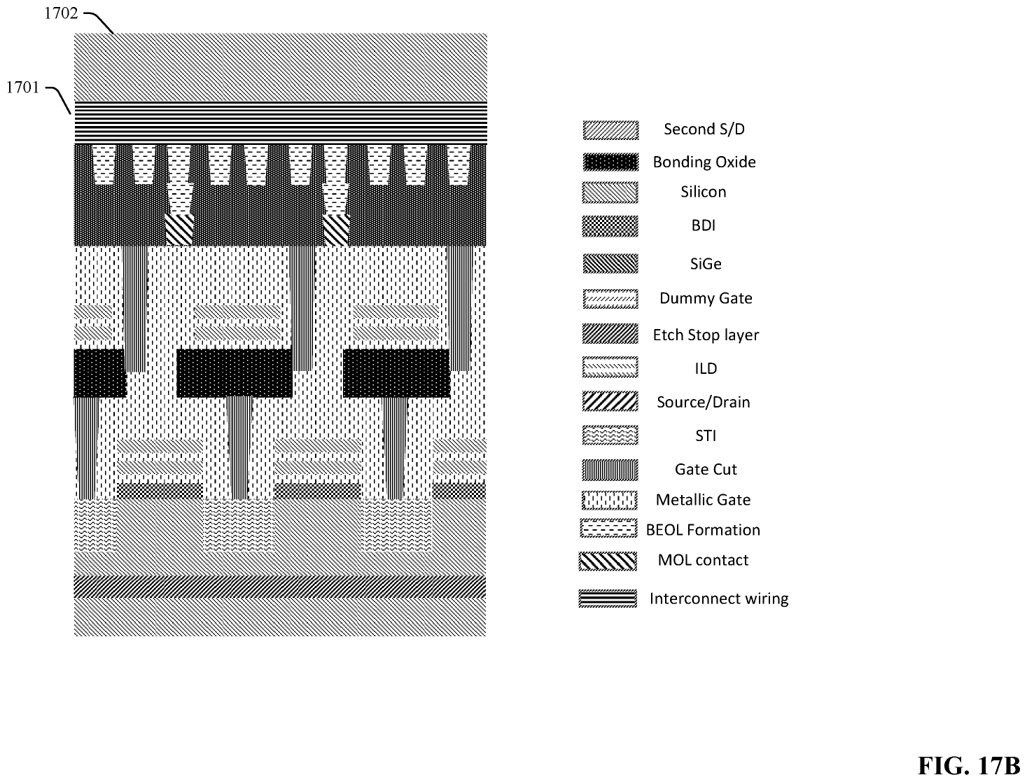

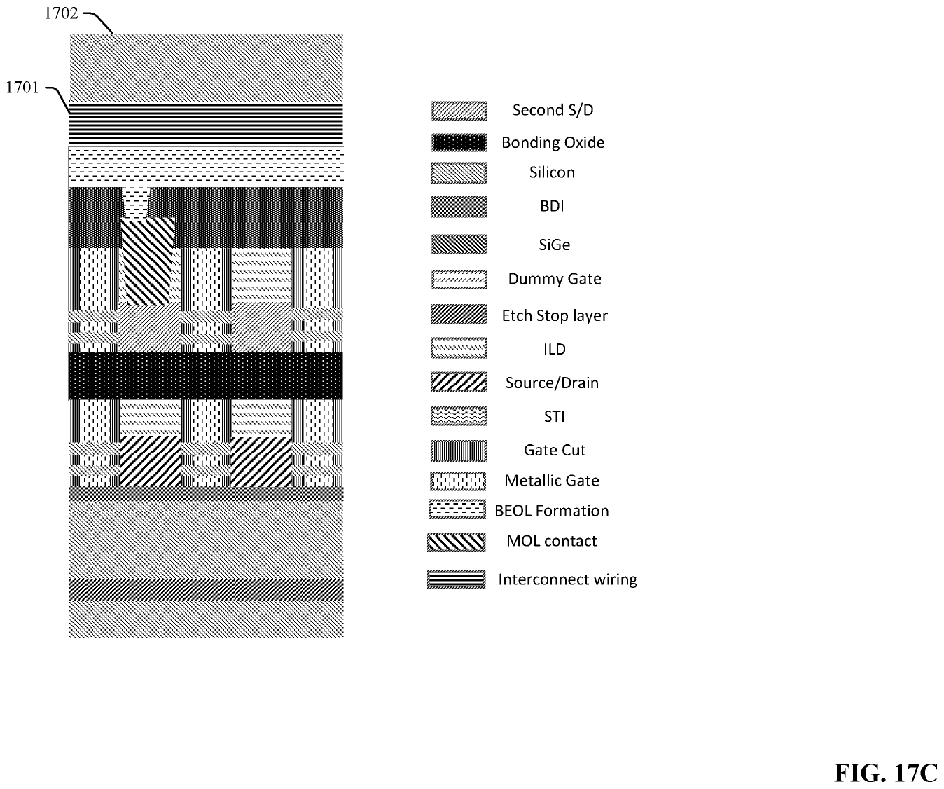

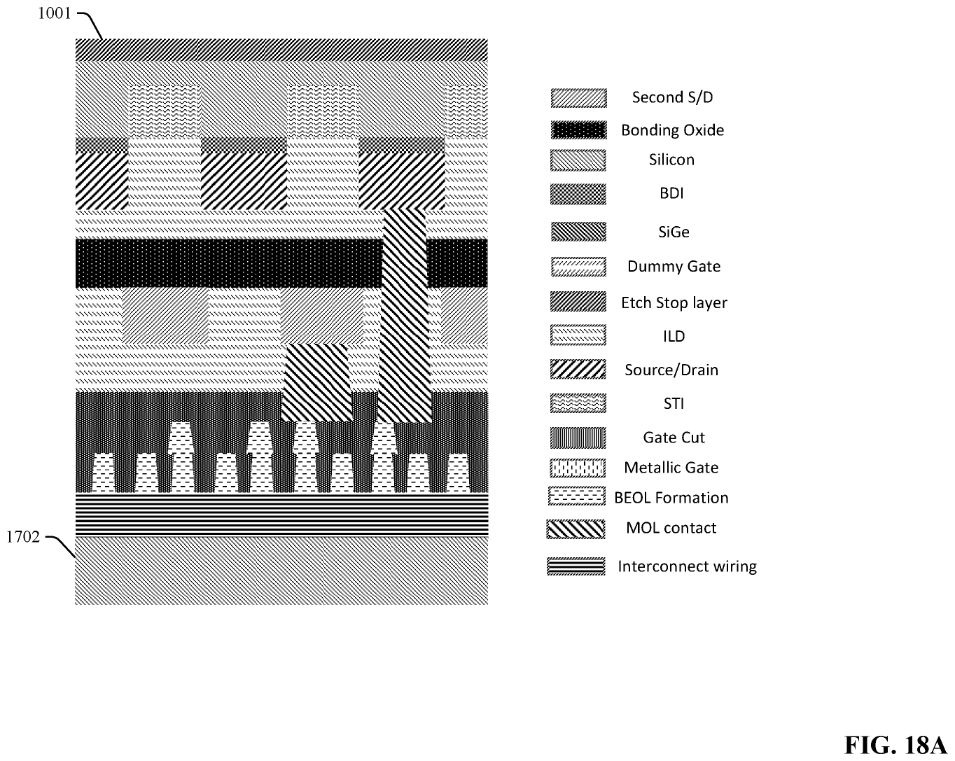

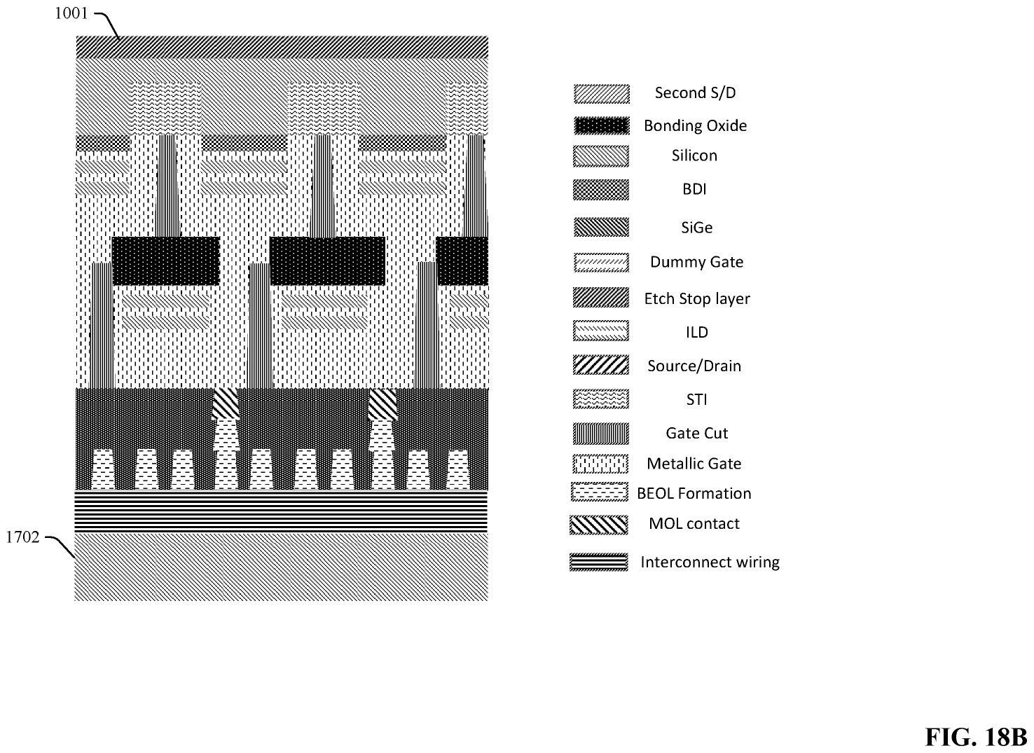

FIGS. 17A, 17B and 17C illustrate cross-sections of an eighth stage of production of device 900 in accordance with one or more embodiments described herein. FIGS. 17A, 17B and 17C comprise interconnect wiring 1701 which connects to lower BEOL formation 1602 and carrier wafer 1702.

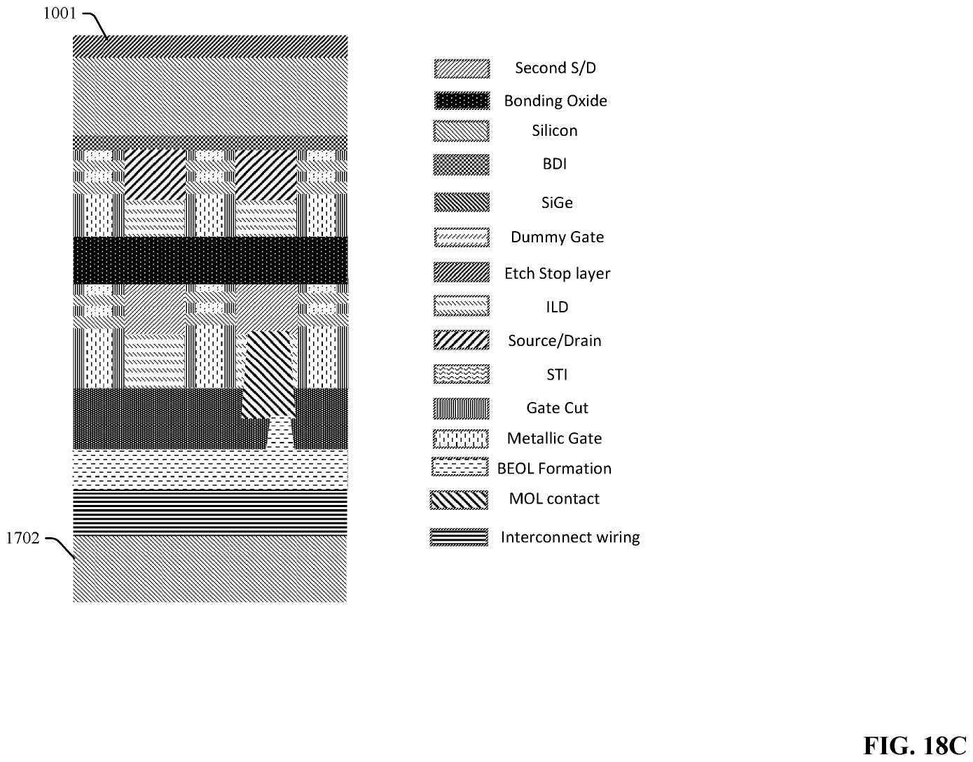

FIGS. 18A, 18B and 18C illustrate cross-sections of a ninth stage of production of device 900 in accordance with one or more embodiments described herein. As shown by FIGS. 18A, 18B and 18C, device 900 can be flipped on to carrier wafer 1702. An etching process can then expose etch-stop layer 1001.

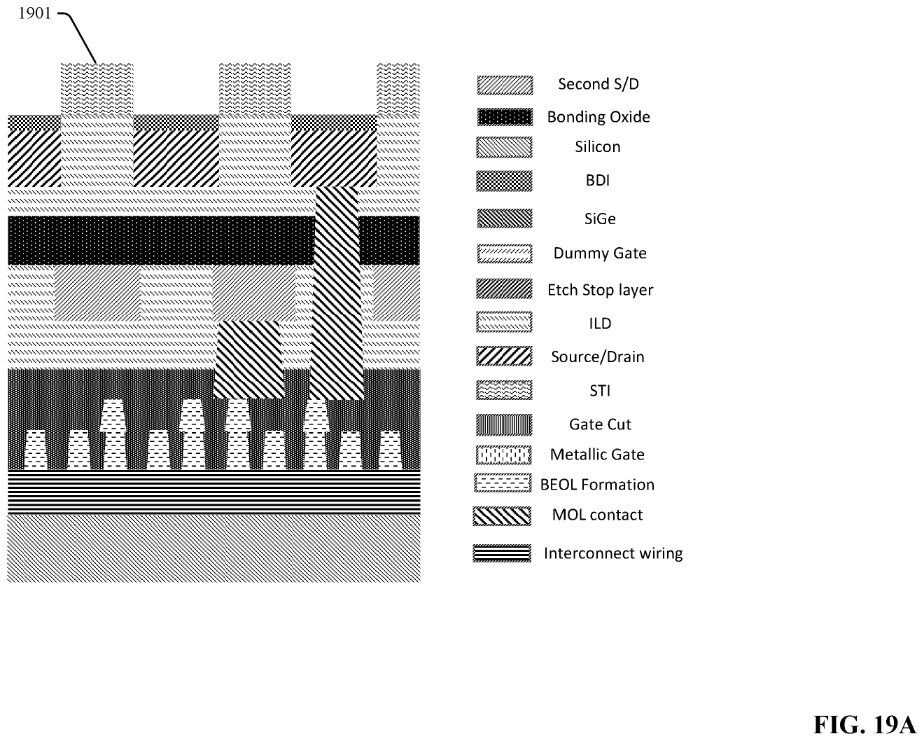

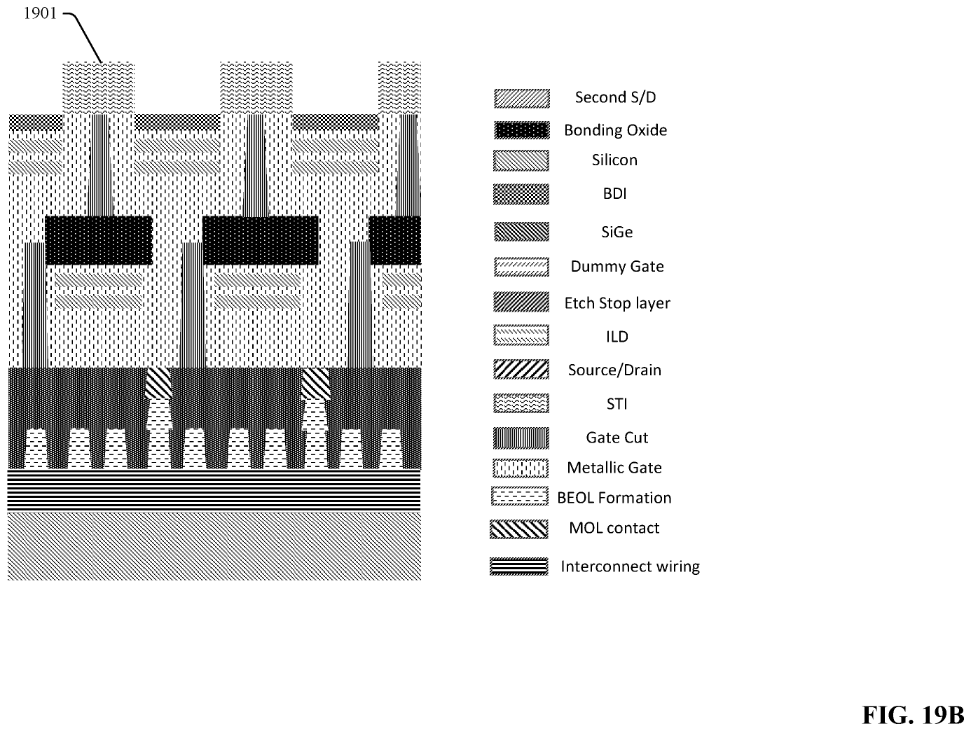

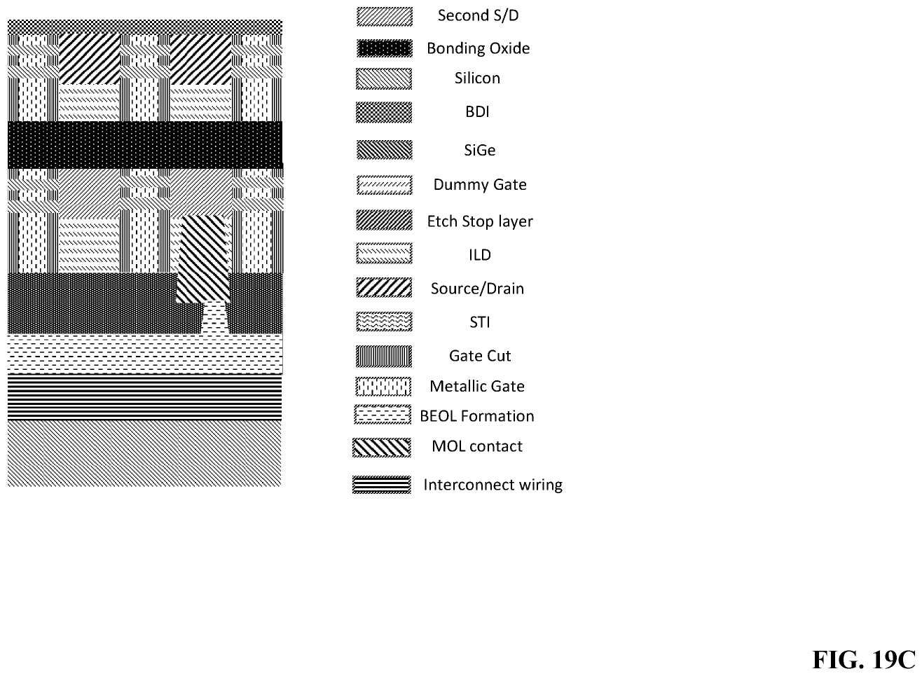

FIGS. 19A, 19B and 19C illustrate cross-sections of a tenth stage of production of device 900 in accordance with one or more embodiments described herein. As shown by FIGS. 19A and 19B, etch-stop layer 1001 and any remaining substrate can be removed to expose shallow trench isolation region 1901.

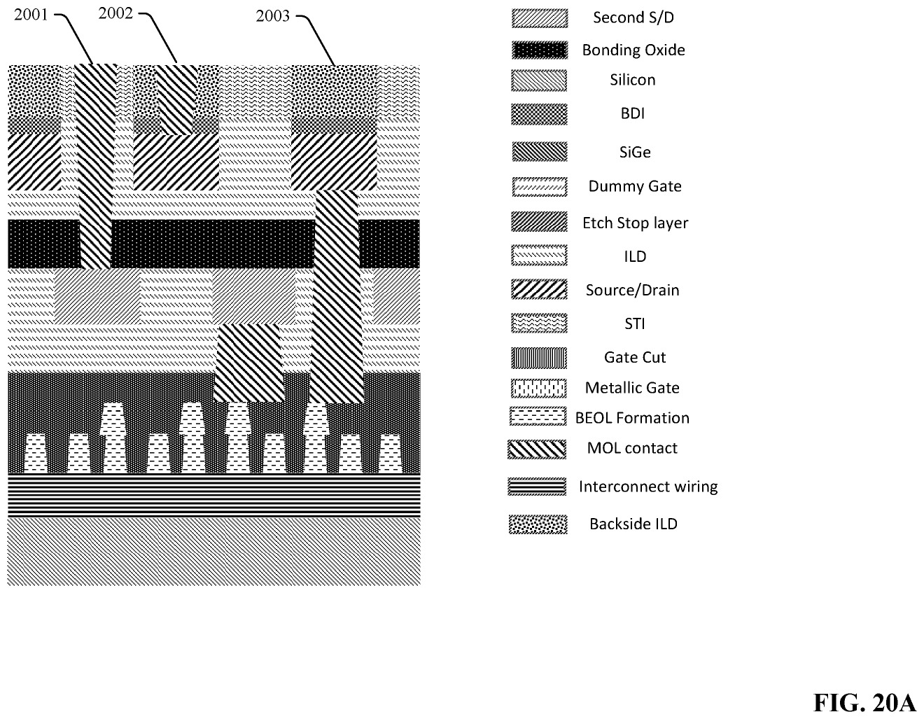

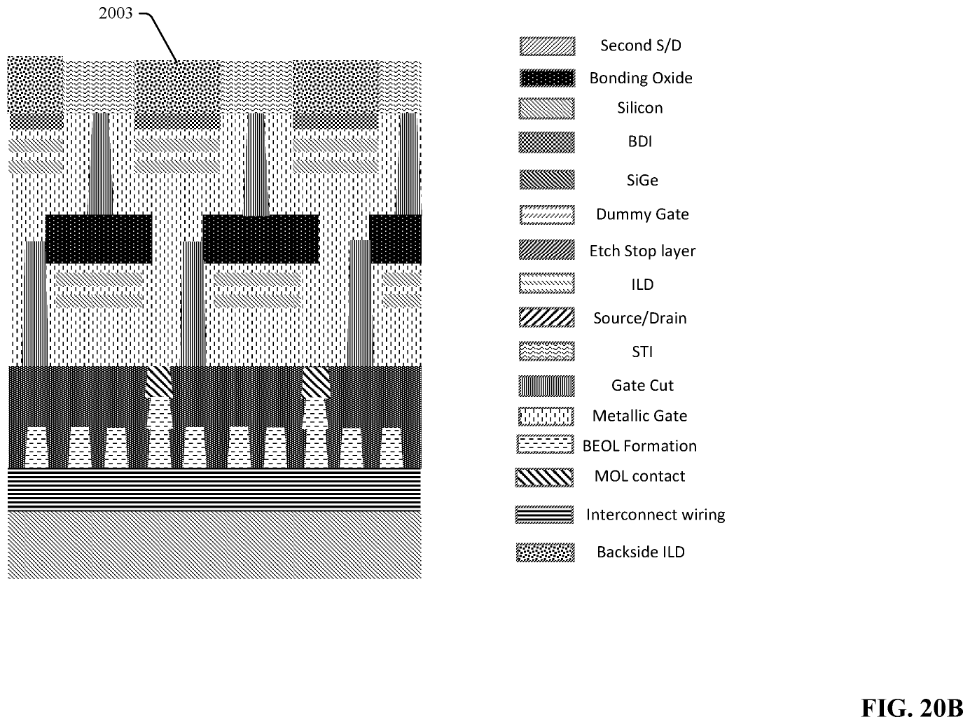

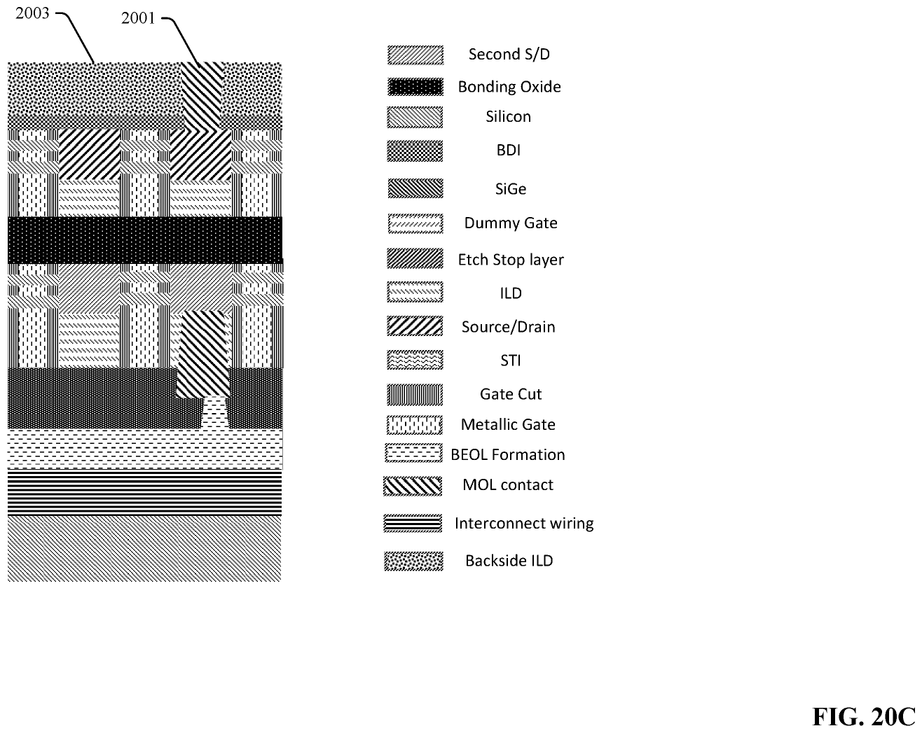

FIGS. 20A, 20B and 20C illustrate cross-sections of an eleventh stage of production of device 900 in accordance with one or more embodiments described herein. FIG. 20A illustrates a cross-section across line 901 of device 900. As shown by FIG. 16A, a first backside connector 2001 can be patterned to connect the one or more second transistor devices to source/drain epi 1204 and a second backside connector 2002 can be patterned to connect the second transistor device 1207 to the first source/drain epi 1004.

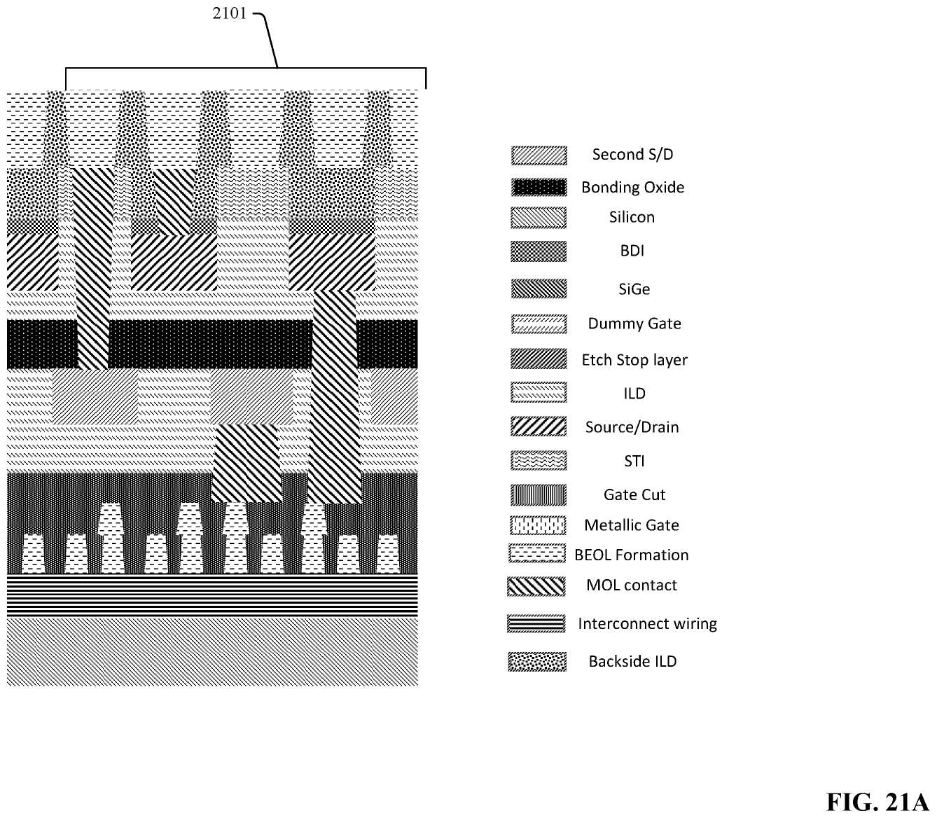

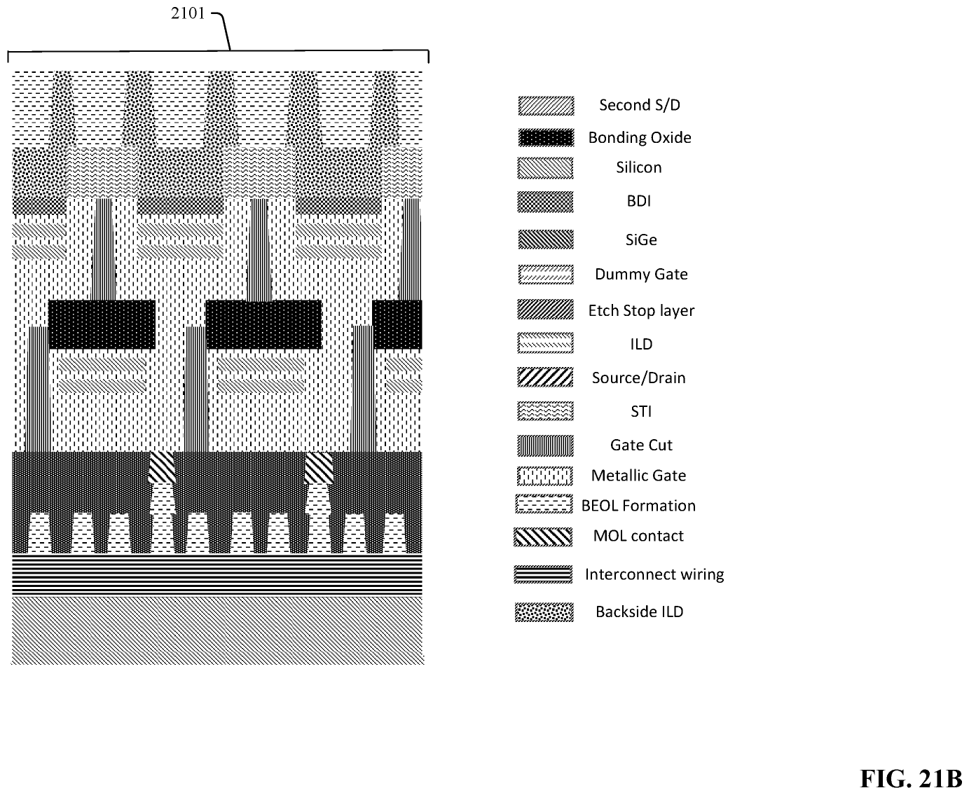

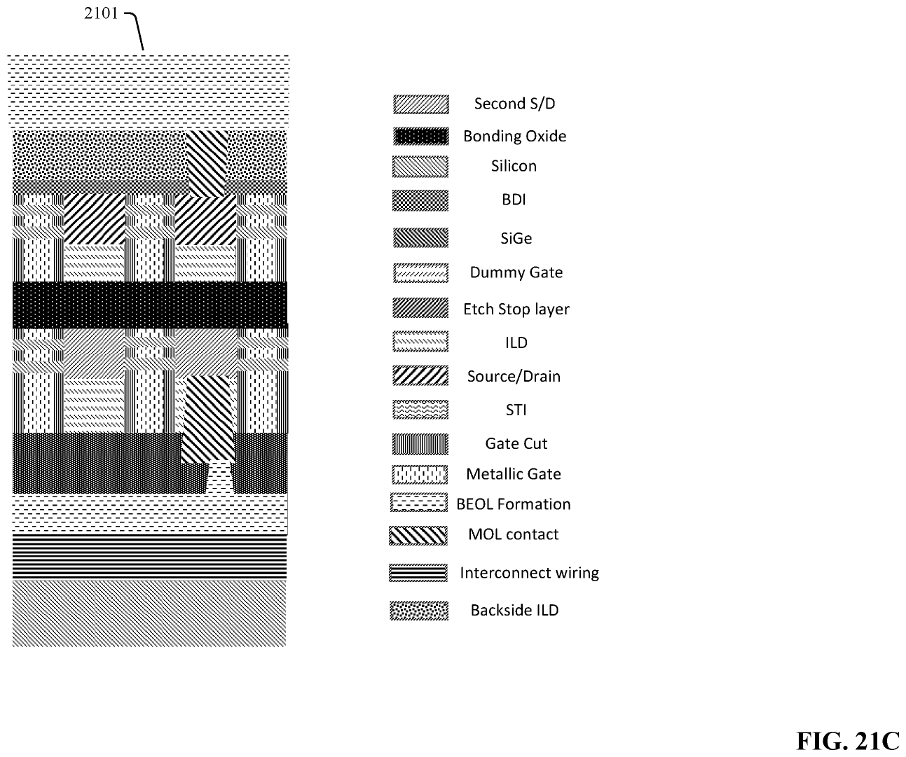

FIGS. 21A, 21B and 21C illustrate cross-sections of a twelfth stage of production of device 900 in accordance with one or more embodiments described herein. As shown by FIGS. 21A, 21B and 21C, a buried power rail layer 2101 comprising one or more buried power rails can be patterned to provide power to the first transistor device 1007 and the second transistor device 1207.

An advantage of such methods, devices, and/or systems is that they enable semiconductor devices with increased decoupling capacitances, which in turn reduce power supply noise. For example, by laterally offsetting stacked FETs, both FETs can be coupled to buried power rails rather than just a single FET with existing devices and methods. By enabling multiple FETs to receive power from buried power rails, the buried power rails can be placed closer to one and other than existing designs, thus increasing decoupling capacitances when compared to existing designs. A practical application of the above-described devices is that they offer improved performance due to increased decoupling capacitances and reduced power supply noise.

What is claimed is:

1. A semiconductor device comprising:
a first transistor stacked on a second transistor, wherein the first transistor is offset laterally from the second transistor; and
a power rail layer comprising a first buried power rail and a second buried power rail, wherein the first buried power rail is coupled to the first transistor and the second buried power rail is coupled to the second transistor.

2. The semiconductor device of claim 1, wherein the first transistor is a p-channel field-effect transistor (PFET).

3. The semiconductor device of claim 1, wherein the second transistor is an n-channel field-effect transistor (NFET).

4. The semiconductor device of claim 1 further comprising:
a gate structure couples the first transistor to the second transistor; and
shared out, wherein the shared out is coupled to the first transistor and the second transistor.

5. The semiconductor device of claim 1, wherein the power rail layer is coupled to a powered back-side delivery network located on a back-side of the semiconductor device.

6. The semiconductor device of claim 1, wherein the first buried power rail and the second buried power rail are spaced unevenly within a cell.

7. A method for fabricating a semiconductor device by a fabrication system, the method comprising:
forming, by the fabrication system, a transistor region on a substrate;
forming, by the fabrication system, an interconnect hierarchy on a top side of the transistor region;
forming, by the fabrication system, a carrier wafer on top of the interconnect hierarchy;
flipping, by the fabrication system, the semiconductor device onto the carrier wafer;
removing, by the fabrication system, the substrate; and
forming, by the fabrication system, two or more buried power rails within a cell.

8. The method of claim 7, further comprising:
coupling, by the fabrication system, the two or more buried power rails to a powered back-side delivery network located on a back-side of the semiconductor device.

9. The method of claim 7, wherein the transistor region comprises a first transistor stacked on a second transistor, wherein the first transistor is offset laterally from the second transistor.

10. The method of claim 9, further comprising:
coupling, by the fabrication system, a first buried power rail of the two or more buried power rails to the first transistor; and
coupling, by the fabrication system, a second buried power rail of the two or more buried power rails to the second transistor.

11. The method of claim 9, wherein the first transistor comprises at least one of a PFET or a NFET.

12. The method of claim 9, wherein the second transistor comprises at least one of a NFET or PFET.

13. The method of claim 9, wherein the transistor region further comprises a gate structure coupling the first transistor to the second transistor.

14. The method of claim 10, wherein the first buried power rail and the second buried power rail are spaced unevenly within the cell.

15. A method for fabricating a semiconductor device by a fabrication system, the method comprising:
stacking, by the fabrication system, a first transistor of the semiconductor device on a second transistor of the semiconductor device, wherein the first transistor is offset laterally from the second transistor;
forming, by the fabrication system, a power rail layer comprising a first buried power rail and a second buried power rail; and
coupling, by the fabrication system, the first buried power rail to the first transistor and the second buried power rail to the second transistor.

16. The method of claim 15 further comprising:
coupling, by the fabrication system, a first end of a gate structure to the first transistor; and
coupling, by the fabrication system, a second end of the gate structure to the second transistor.

17. The method of claim 15, wherein the first transistor is a p-channel field-effect transistor (PFET).

18. The method of claim 15, wherein the second transistor is an n-channel field-effect transistor (NFET).

19. The method of claim 15 further comprising:
coupling, by the fabrication system, the power rail layer to a powered back-side delivery network.

20. The method of claim 15, wherein the first buried power rail and the second buried power rail are spaced unevenly within a cell.
